(19) United States
(12) Patent Application Publication
(10) Pub. No.: US 2008/0047134 A1
(43) Pub. Date: Feb. 28, 2008

(54) METHOD OF MANUFACTURING FLEXIBLE PRINTED CIRCUIT BOARD

(75) Inventors: Koji TSURUSAKI, Sakura-shi (JP); Osamu NAKAO, Sakura-shi (JP); Fumitaka AIZAWA, Sakura-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIKURA LTD., Tokyo (JP)

(21) Appl. No.: 11/830,597

(22) Filed: Jul. 30, 2007

(30) Foreign Application Priority Data
Aug. 2, 2006 (JP) 2006-211088

(51) Int. Cl. H05K 3/00

(52) U.S. Cl. 29/829

(57) ABSTRACT

Provided are methods of manufacturing a flexible printed circuit board having a surface layer portion where a copper foil circuit is disposed and consisting single-side board, double-side board and multi-layer board. A first manufacturing method in a case when a single-sided CCL is used includes at least a step in which the surface layer portion is subjected to alkaline treatment, and a step to dispose a resist onto the alkaline-treated surface layer portion.

This application claims priority from Japanese Patent Application No. 2006-211088, the disclosure of which is incorporated herein by reference

### TECHNICAL FIELD

Methods consistent with the present invention relate to a method of manufacturing a flexible printed circuit board and more specifically a method of manufacturing a flexible printed circuit board with excellent adhesive strength of a surface layer portion between a resist or coverlay when the coverlay is laminated onto a surface layer portion of a copper foil circuit and the coverlay film is provided so as to contact a resist or an adhesive therewith.

### DESCRIPTION OF THE RELATED ART

A flexible printed circuit board is used in various electronic components due to its thinness and flexibility. In particular, a high flex resistance is required in a flexible printed circuit board used in such as a hinge section of a folding-typed cell phone or terminal of PDA.

When manufacturing a flexible printed circuit board, a resist or coverlay film (hereinafter abbreviated as CL) may be disposed on a circuit which is formed of a copper foil (hereinafter called a copper foil circuit) of a Copper-Clad Laminate (CCL) provided on a surface layer portion having the function of providing electrical insulation on the copper foil circuit or protection from external physical damage. The resist used in this area is mainly classified into liquid and a film types; it is not limited to any of the types in the structures described below.

The flexible printed circuit board is categorized by the number of conductor layers so that one, two, and more than three layers are called as single-side board, double-side board and multi-layer board, respectively.

For example, manufacturing methods shown in FIGS. 11A to 11C and FIGS. 12A to 12C are used for a single-side board. FIGS. 11A to 11C and FIGS. 12A to 12C show examples of providing a resist and a CL via adhesive, respectively.

(Example of Providing a Resist on a Surface Layer Portion on a Single-Side Board)

(A1) A circuit 112′ (hereinafter also called a copper foil circuit) is formed by processing a conductive member 112 on a single-sided CCL 110 (FIG. 11A) consisting of the conductive member 112 (such as a copper-foil) disposed on one side of a flexible base 111 with electrical insulating properties, to obtain a single-sided CCL 110′ provided with the circuit 112′ (FIG. 11B).

(A2) A FPC 130 is obtained (FIG. 11C) consisting of a structure with a resist 120 laminated on a surface layer portion where a copper foil circuit is disposed, by laminating a solder resist 120 (hereinafter abbreviated as a resist) onto a surface of a single-sided CCL 110′ where the circuit 112′ is disposed.

(Example of Providing a CL on a Surface Layer Portion of a Single-Side Board via Adhesive)

(B1) A circuit 112′ (hereinafter also called as a copper foil circuit) is formed by processing a conductive member 112 on the single-sided CCL 110 (FIG. 12A) consisting of the conductive member 112 (such as a copper foil) disposed on one side of a flexible base 111 with electrical insulating properties, to obtain a single-sided CCL 110′ provided with the circuit 112′ (FIG. 12B).

(B2) A FPC 140 is obtained (FIG. 12C), consisting of a structure with a coverlay 121 laminated on a surface layer portion where a copper foil circuit is disposed, by laminating a flexible base 123 with electrical insulating properties via an adhesive 122 onto a surface of a single-sided CCL 110′ where the circuit 112′ is disposed.

Thus as shown in FIGS. 11A to 11C, when adhesion is weak between the copper foil circuit 112′ and the resist 120 (portion shown in α), there is a possibility of peeling between these members eventually occurring due to environmental tests such as heat-cycle tests or age deterioration. For instance, when peeling occurs between the copper film and resist, it is not desirable to use as a printed circuit board due to insulation failure. On the other hand, when peeling occurs between the flexible base (for instance polyimide) 111 and the resist 120 (portion shown in β), there may be a possibility of expansion upon a reflow process, a chemical solution may leak into the circuit board at a post-laminating process or insulation failure may occur.

Therefore, it is required to laminate between the copper foil circuit 112′ consisting of the surface layer portion, the flexible base 111 and the resist 120 with a sufficient adhesive strength in the FPC base 130, such as the structures shown in FIGS. 11A to 11C.

The problems of the surface layer portion (copper foil circuit or flexible base) described above are the same as those configuration examples provided with a coverlay instead of the resist as shown in FIGS. 12A to 12C. Therefore, it is required to laminate between the copper foil circuit 112′ consisting of the surface layer portion, and the adhesive 122 consisting of the flexible base 111 and a coverlay 121 with a sufficient adhesive strength in the FPC base 140 such as the structures shown in FIGS. 12A to 12C.

In the conventional manufacturing methods, adhesive strength may be weak between the copper foil circuit 112′ consisting of the surface layer portion and the resist after disposing the resist as shown in FIGS. 11A to 11C. In this case, peeling more likely occurs in the corresponding portion so that there is a possibility of reducing the yield due to leakage of a chemical solution in a step following disposing the resist, such as film developing steps, which may result in a decrease in reliability of printed circuit boards as industrial products. This is the same as a case where film-types of CL are used instead of the resist as shown in FIGS. 12A to 12C.

Manufacturing methods for overcoming the problems above may include (I) a method of modifying a polyimide surface by alkaline treatment after treating the polyimide surface to be electrically discharged see e.g. (JP-A-5-279497), (II) a method of modifying a polyimide surface by alkaline solution after subjecting the polyimide surface to plasma treatment at low temperature see e.g. (JP-A-6-032926), (III) a method of modifying a polyimide film surface by an aqueous acidic solution after subjecting the surface to alkaline aqueous solution treatment see e.g. (JP-A-7-003055), (IV) a method of modifying a polyimide film surface by plasma treatment in an active gas atmosphere after subjecting the surface to plasma treatment in an inert gas atmosphere see e.g. (JP-A-8-003338), and (V) a method of modifying a polyimide resin surface by etching with a second oxidizing agent after irradiating the polyimide resin surface with ultraviolet rays in the presence of a first oxidizing agent (JP-A-9-157417). Note that the polyimide in each Patent document corresponds to the electrically insulating flexible substrate 111 consisted of the FPC substrate 130 and 140 described above.

However, the above-mentioned publications (I) to (V) disclose only that a surface is subjected to the alkaline or plasma treatment for improving adhesiveness, but do not specify detailed treatment conditions such as concentration, temperature of the alkaline solution and treatment time. In other words, these publications have no disclosure of optimum conditions of surface treatment for each condition.

In addition, there has been proposed (VI) a multi-layered printed circuit board suitable for heat-resistant flip-chip mounting, and a method of manufacturing the same see e.g. (JP-A-9-298369). This publication discloses an appropriate range of modulus of elasticity and coefficient of linear expansion of an adhesive layer and composition of an adhesive.

In addition, there has been proposed (VII) a multi-layered printed circuit board in which a via hole is hardly peeled from a lower layer of a conductor circuit see e.g. (JP-A-11-046066). This publication discloses an appropriate range of particle diameter and weight proportion of an epoxy resin as an adhesive layer.

In addition, there has been proposed (VIII) a multi-layered printed circuit board having excellent adhesive strength between a conductor layer and an insulating layer, but the publication merely discloses a surface roughening treatment method see e.g. (Japanese Patent Application Publication No. Hei10-070367).

In addition, there has been proposed (IX) an adhesive for a flexible printed circuit board and a composition of the adhesive see e.g. (JP-A-2001-164226).

Although the above-mentioned publications (VI) to (IX) disclose the types and proportion of the adhesives and how to perform a surface treatment of the adhesives used in the conventional printed circuit boards, there are no disclosures of improving adhesiveness under optimum conditions of alkaline treatment.

In recent years, with increased lightness, thinness, shortness and miniaturization of electronic devices, there has been a need for a printed circuit board with high density interconnections. Since a Flexible Printed Circuit (FPC) has a base thinner than Rigid Printed Circuit (RPC) board and is advantageous to formation of a fine circuit over the RPC, a multi-layered FPC (hereinafter also called FPC multi-layered substrate) is sufficient to satisfy the need. Accordingly, in the multi-layered FPC, it is obvious that a certain adhesive strength is required between the copper foil circuit and resist which consists of the surface layer portion. Therefore, establishing specific treatment conditions for a method of treating a surface of a member where the resist is disposed in the multi-layered FPC is desired.

### SUMMARY

Exemplary embodiments of the present invention were conceived in view of the above-described circumstances and have as an exemplary objective the provision of a method of manufacturing a flexible printed circuit board including a surface layer portion where a copper film circuit is disposed and includes a single-side board, double-side board and multi-layer board, which is capable of preventing the resist or the coverlay from being peeled from the surface layer portion.

According to one exemplary embodiment, there is provided a method of manufacturing a flexible printed circuit board including a single-side board, double-side board and multi-layer board provided with a surface layer portion where a copper film circuit is disposed. The method includes at least one step in which the surface layer portion is subjected to alkaline treatment, and a second step to dispose a resist on the alkaline-treated surface layer portion. The first step is conducted under conditions of an alkaline solution with a concentration of 0.2 wt % or more and 4.0 wt % or less, and with a temperature of 20° C. or more and 50° C. or less and treatment time of 20 seconds or more and 200 seconds or less.

According to a second exemplary embodiment, there is provided a method of manufacturing a flexible printed circuit board including a single-side board, double-side board and multi-layer board provided with a surface layer portion where a copper film circuit is disposed. The method includes at least one step in which the surface layer portion is subjected to alkaline treatment, and a second step to dispose a coverlay on the alkaline-treated surface layer portion so as to attach an adhesive. The first step is conducted under conditions of an alkaline solution with a concentration of 0.2 wt % or more and 4.0 wt % or less, and with a temperature of 20° C. or more and 50° C. or less and a treatment time of 20 seconds or more and 200 seconds or less.

According to the first exemplary embodiment, above, a surface of a copper foil circuit is modified by subjecting the surface layer portion where the copper foil circuit is disposed to an alkaline treatment in the first step. Next, a resist is disposed in the second step to cover the modified surface of the copper foil circuit by the alkaline treatment. As a result, the resist has excellent adhesion strength to the modified surface of the copper foil circuit. In order to obtain stable and excellent adhesion strength, the conditions of the first step may be set up as an alkaline solution with a concentration of 0.2 wt % or more and 4.0 wt % or less, with a temperature of 20° C. or more and 50° C. or less and a treatment time of 20 seconds or more and 200 seconds or less.

According to the second exemplary embodiment above, the surface of the copper foil circuit is modified by subjecting the surface layer portion where the copper foil circuit is disposed to an alkaline treatment in the first step. In the subsequent step, the coverlay is laminated to cover the modified surface of the copper foil circuit by the alkaline treatment and to contact an adhesive consisting of the coverlay with the surface layer portion. As a result, the adhesive consisting of the coverlay has excellent adhesion strength to the modified surface of the copper foil circuit. In order to obtain stable and excellent adhesion strength, the conditions of step γ may be set up as an alkaline solution with a concentration of 0.2 wt % or more and 4.0 wt % or less, with a temperature of 20° C. or more and 50° C. or less and treatment time of 20 seconds or more and 200 seconds or less.

Therefore, the two manufacturing methods described above contribute to the provision of a reliable flexible printed circuit board with stable adhesive strength in which only the surface layer portion where the copper foil circuit is disposed is subjected to an alkaline treatment so that adhesive strength between the surface layer portion where the copper foil circuit is disposed and the resist or the coverlay is remarkably improved when the coverlay is laminated to the surface layer portion so as to contact with the resist or the adhesive.

### BRIEF DESCRIPTION OF THE DRAWINGS

FIG. 1A is a cross-sectional view showing an example of a first manufacturing method of a FPC according to the present invention.

FIG. 1B is a cross-sectional view showing an example of a first manufacturing method of a FPC according to the present invention.

FIG. 1C is a cross-sectional view showing an example of a first manufacturing method of a FPC according to the present invention.

FIG. 1D is a cross-sectional view showing an example of a first manufacturing method of a FPC according to the present invention.

FIG. 2A is a cross-sectional view showing an example of a second manufacturing method of a FPC according to the present invention.

FIG. 2B is a cross-sectional view showing an example of a second manufacturing method of a FPC according to the present invention.

FIG. 2C is a cross-sectional view showing an example of a second manufacturing method of a FPC according to the present invention.

FIG. 2D is a cross-sectional view showing an example of a second manufacturing method of a FPC according to the present invention.

FIG. 3A is a cross-sectional view showing another example of a first manufacturing method of a FPC according to the present invention.

FIG. 3B is a cross-sectional view showing another example of a first manufacturing method of a FPC according to the present invention.

FIG. 3C is a cross-sectional view showing another example of a first manufacturing method of a FPC according to the present invention.

FIG. 3D is a cross-sectional view showing another example of a first manufacturing method of a FPC according to the present invention.

FIG. 3E is a cross-sectional view showing another example of a first manufacturing method of a FPC according to the present invention.

FIG. 3F is a cross-sectional view showing another example of a first manufacturing method of a FPC according to the present invention.

FIG. 4A is a cross-sectional view showing another example of a second manufacturing method of a FPC according to the present invention.

FIG. 4B is a cross-sectional view showing another example of a second manufacturing method of a FPC according to the present invention.

FIG. 4C is a cross-sectional view showing another example of a second manufacturing method of a FPC according to the present invention.

FIG. 4D is a cross-sectional view showing another example of a second manufacturing method of a FPC according to the present invention.

FIG. 4E is a cross-sectional view showing another example of a second manufacturing method of a FPC according to the present invention.

FIG. 4F is a cross-sectional view showing another example of a second manufacturing method of a FPC according to the present invention.

FIG. 5 is an example of graphs showing a relationship between an alkaline treatment concentration and a peel strength.

FIG. 6 is another example of graphs showing a relationship between an alkaline treatment concentration and a peel strength.

FIG. 7 is an example of graphs showing a relationship between an alkaline treatment time and a peel strength.

FIG. 8 is another example of graphs showing a relationship between an alkaline treatment time and a peel strength.

FIG. 9 is an example of graphs showing a relationship between an alkaline treatment solution temperature and a peel strength.

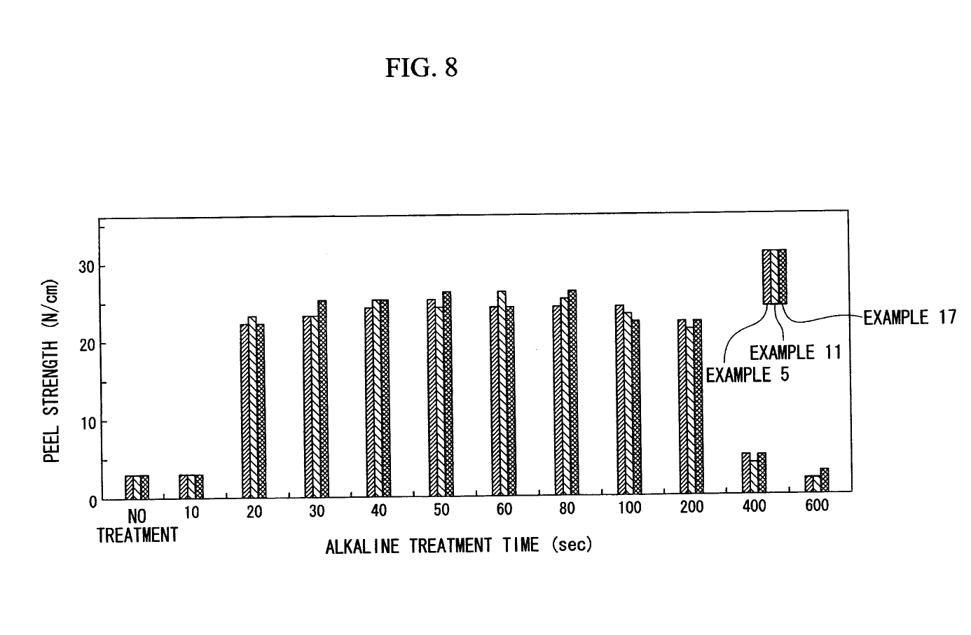

FIG. 8 is another example of graphs showing a relationship between an alkaline treatment solution temperature and a peel strength.

FIG. 11A is a cross-sectional view showing an example of a conventional FPC manufacturing method.

FIG. 11B is a cross-sectional view showing an example of a conventional FPC manufacturing method.

FIG. 11C is a cross-sectional view showing an example of a conventional FPC manufacturing method.

FIG. 12A is a cross-sectional view showing another example of a conventional FPC manufacturing method.

FIG. 12B is a cross-sectional view showing another example of a conventional FPC manufacturing method.

FIG. 12C is a cross-sectional view showing another example of a conventional FPC manufacturing method.

### DETAILED DESCRIPTION OF EXEMPLARY EMBODIMENTS OF THE INVENTION

Hereinafter, the manufacturing method of a flexible printed circuit board will be described through exemplary embodiments with reference to the accompanying drawings.

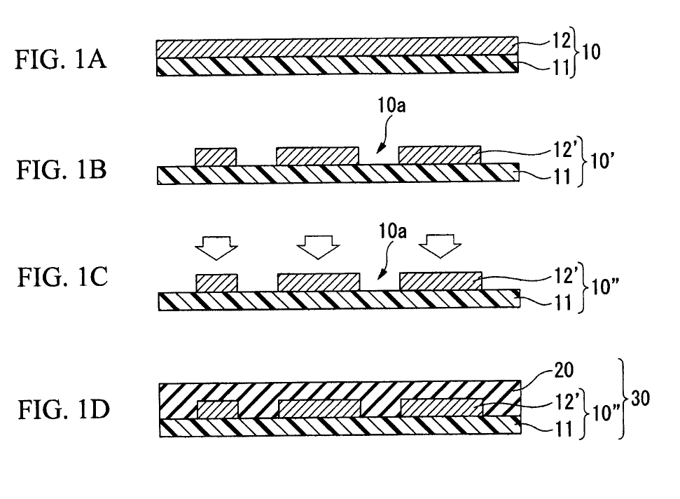

FIGS. 1A to 1D are cross-sectional views of an example of a first manufacturing method (when a single-side board is used) of a flexible printed circuit board (FPC) according to the present invention and the components are enlarged ad libitum.

A first exemplary manufacturing method is applied to a flexible printed circuit (single-side board) 30 which includes a surface layer portion 10a where a copper foil circuit 12′ is provided on one side of a flexible base 11 and a resist 20 disposed by laminating onto the surface layer portion 10a, such as shown in FIGS. 1B to 1D.

Here, although a manufacturing method is described with a single-side board taken as an example of the flexible printed circuit, it is not limited and can be applied to flexible printed circuits boards with a double-side board or multi-layer board provided with a surface layer portion where the copper foil circuit is disposed as described later, as long as effects and actions of an alkaline treatment of the present application are maintained.

According to the first manufacturing method, in any flexible printed circuit boards, a surface of a copper foil circuit is modified by subjecting the surface layer portion of CCL where the copper foil circuit is disposed to an alkaline treatment in the first step. Next, a resist is disposed in a second step to cover the modified surface of the copper foil circuit by the alkaline treatment. As a result, the resist has excellent adhesion strength to the modified surface of the copper foil circuit with improved adhesive strength between the resist and the surface layer portion where the copper foil circuit is disposed so that a flexible printed circuit board with high reliability and stable adhesive strength is obtained.

Example in Which the First Manufacturing Method is Applied to a Single-Side Board:

(A11) A circuit is formed on one side of a flexible base. A circuit 12′ (hereinafter also called a copper foil circuit) is formed by etching a conductive member 12 using a CCL10 (FIG. 1A) provided with the conductive member (for instance copper foil) 12 on one side of a flexible base 11 made of polyimide, and a single-sided CCL10′ provided with a circuit 12′ is obtained (FIG. 1B).

(A12) At least one side of the single-sided CCL10′ where the circuit 12′ is provided is subjected to an alkaline treatment (FIG. 1C). An arrow shown in FIG. 1C indicates the alkaline treatment being conducted on only a surface where the circuit 12′ is disposed. However both sides (both outer sides) of the single-sided CCL10′ may be subjected to the alkaline treatment simultaneously if necessary. For instance, an alkaline treatment of both outer surfaces of the single-sided CCL10′ is conducted by spraying a concentration- and a temperature-regulated alkaline aqueous solution from a device in which the line speed is controlled to the base. Accordingly, the alkaline-treated single-sided CCL10″ is obtained.

(A13) A solder resist (hereinafter abbreviated as a resist) 20 is laminated onto the side where the circuit 12′ is disposed on the alkaline-treated single-sided CCL10″ in the previous step. From the step above, a flexible printed circuit (hereinafter abbreviated as a FPC) 30 which consists of a resist 20 laminated onto the surface layer portion where the copper foil circuit is disposed is obtained (FIG. 1D). When this lamination is performed, pressure or heat may be applied toward a direction of the flexible base 11 from the resist 20 (from the external to internal direction) as required. Therefore, the FPC 30 provided with a resist onto the surface layer portion of single-side board as shown in FIG. 1D is formed from the above steps A11 to A13.

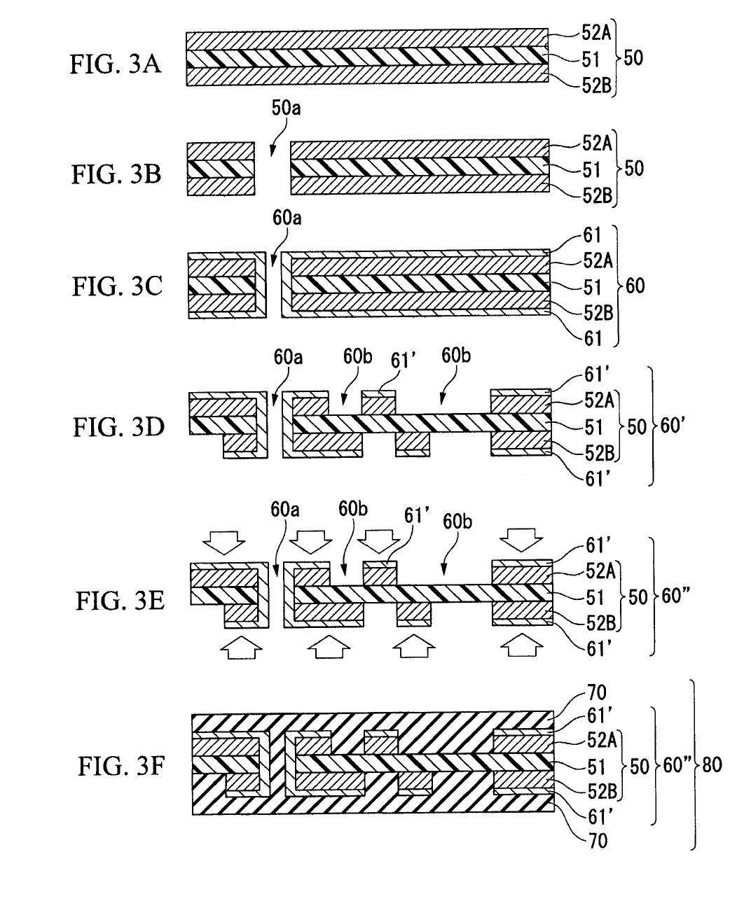

FIGS. 3A to 3F are cross-sectional views of an example from a first manufacturing method (when a double-side board is used) of a flexible printed circuit board (FPC) according to an exemplary embodiment and the components are enlarged ad libitum. FIGS. 3A to 3F show that the first manufacturing method of the present invention is effective by replacing a single-side board with double-side board.

Example in Which the First Manufacturing Method is Applied to a Double-Side Board:

(A21) A through-hole is formed on a flexible base where a conductive member is disposed onto both sides. A through-hole 50a is formed onto a CCL50 (FIG. 3B) by such as a dry etching method using the CCL50 (FIG. 3A) where each of first conductive members (for instance copper foil) 52A and 52B is disposed onto each side of a flexible base 51 formed of polyimide.

(A22) A double-sided CCL 60 provided with a second conductive member 61 so as to cover an internal wall of the through-hole 50a is obtained by plating the CCL50 where the through-hole 50a is disposed (FIG. 3C).

(A23) A double-sided CCL 60′ provided with a circuit 61′ is obtained by forming a circuit 61′ by etching an area where the second conductive member 61 is superimposed onto the first conductive member 52A and 52B with a double-sided CCL 60 provided with the second conductive member 61 (FIG. 3D).

(A24) An alkaline treatment is conducted onto both surfaces at least where the circuit 61′ is disposed in the double-sided CCL 60′ (hereinafter called a step α) (FIG. 3E). For instance, an alkaline treatment of both outer surfaces of the double-sided CCL60′ is conducted by spraying a concentration- and a temperature-regulated alkaline aqueous solution from a device in which the line speed is controlled to the base. Accordingly, an alkaline-treated double-sided CCL60″ is obtained.

(A25) A solder resist (hereinafter abbreviated as a resist) 70 is laminated onto a surface where the alkaline-treated circuit 61′ is disposed on the double-sided CCL60″ in the previous step.

From the step above, a flexible printed circuit (hereinafter abbreviated as FPC) 80 which consists of the resist 70 laminated onto the surface layer portion where the copper foil circuit is disposed is obtained (FIG. 3F). When this lamination is performed, pressure or heat may be applied to the direction from the resist 70 to the flexible base 51 (from the external to internal direction) as required. Therefore, the FPC 80 provided with a resist on the surface layer portion of the double-side boards as shown in FIG. 3F is formed from the steps A21 to A25, above.

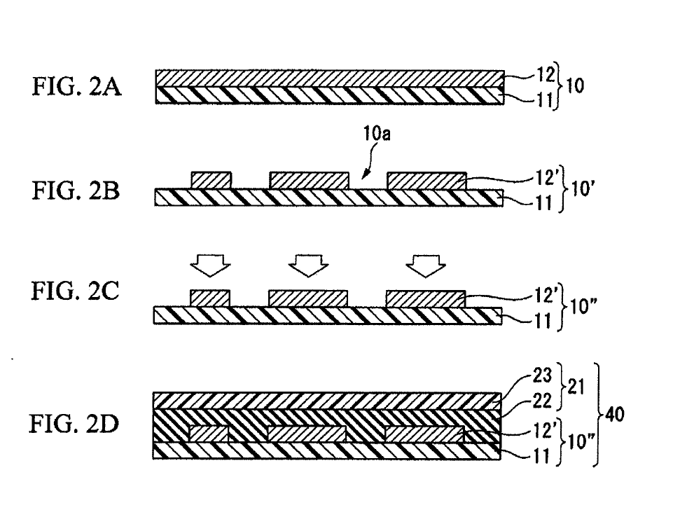

FIGS. 2A to 2D are cross-sectional views of an example of a second manufacturing method (when single-side board is used) of a flexible printed circuit board (FPC) and the components are enlarged ad libitum.

The second manufacturing method is applied to a flexible printed circuit (single-side board) 40 which includes a surface layer portion 10a where the copper foil circuit 12′ is provided on one side of the flexible base 11, and an adhesive 22 which is included in a coverlay 21 so as to laminate into the surface layer portion 10a.

Here, although a manufacturing method of the flexible printed circuit is described with a single-side board taken as an example, it is not limited and can be applied to flexible printed circuits with a double-side board or multi-layer board provided with a surface layer portion where the copper foil circuit is disposed as described later, as long as effects and action of an alkaline treatment of the present application are maintained.

According to the second manufacturing method, in any flexible printed circuit boards, a surface of a copper foil circuit is modified by subjecting the surface layer portion of CCL where the copper foil circuit is disposed to the alkaline treatment in the first step. Next, a resist is disposed in the second step in order to attach the adhesive to the modified surface of the copper foil circuit by the alkaline treatment. As a result, the adhesive has excellent adhesion strength to the modified surface of the copper foil circuit with improved adhesive strength between the coverlay and the surface layer portion where the copper foil circuit is disposed so that a flexible printed circuit board with high reliability and stable adhesive strength is obtained.

Example in Which the Second Manufacturing Method is Applied to a Single-Side Board:

(B11) A circuit is formed on one side of a flexible base. The circuit 12′ (hereinafter also called a copper foil circuit) is formed by etching the conductive member 12 using a CCL 10 (FIG. 2A) provided with the conductive member (for instance copper foil) 12 on one side of the flexible base 11 made of polyimide, and the single-sided CCL 10′ provided with the circuit 12′ is obtained (FIG. 2B).

(B12) At least one side of the single-sided CCL10′ where the circuit 12′ is provided is subjected to an alkaline treatment (FIG. 2C). An arrow shown in FIG. 2C indicates the alkaline treatment being conducted on only a surface where the circuit 12′ is disposed. However both sides (both outer sides) of the single-sided CCL 10′ may be subjected to the alkaline treatment simultaneously if necessary. For instance, alkaline treatment of both outer surfaces of the single-sided CCL10′ is conducted by spraying a concentration- and a temperature-regulated alkaline aqueous solution from a device in which the line speed is controlled to the base. Accordingly, the alkaline-treated single-sided CCL 10″ is obtained.

(B13) The coverlay 21 is laminated onto a surface where the alkaline-treated circuit 12′ is disposed on the single-sided CCL10″ in the previous step in order to contact the adhesive. From the step above, a flexible printed circuit (hereinafter abbreviated as a FPC) 40 which consists of the coverlay 21 laminated onto the surface layer portion where a copper foil circuit is disposed is obtained (FIG. 2D). When this lamination is performed, pressure or heat may be applied toward a direction of the flexible base 11 from the coverlay 21 (from the external to internal direction) as required. As for the types of the coverlay, a coverlay consisting of, for instance, the adhesive 22 and a flexible base 23 may be preferably used.

Therefore, a FPC 40 provided with a coverlay onto the surface layer portion of single-side board as shown in FIG. 2D is formed from the steps (B11) to (B13).

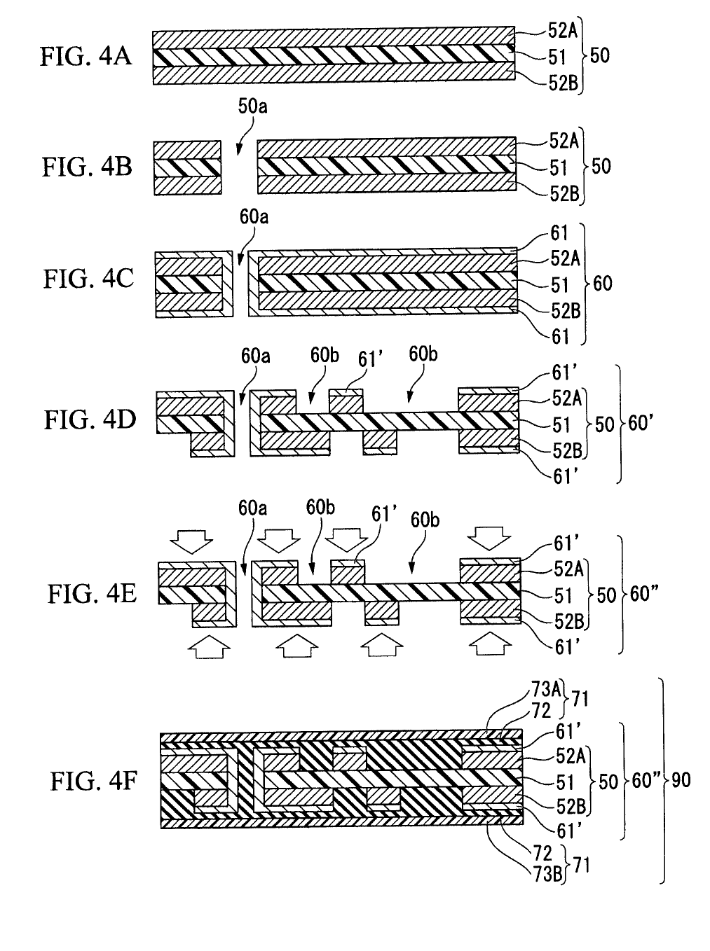

FIGS. 4A to 4F are cross-sectional views of an example of a second manufacturing method (when double-side board is used) of a flexible printed circuit board (FPC) according to the present invention and the components are enlarged ad libitum.

FIGS. 4A to 4F describe the second manufacturing method and is effective by replacing single-side board with double-side board.

Example in Which the First Manufacturing Method Applied to a Double-Side Board:

(B21) A through-hole is formed on a flexible base where a conductive member is disposed onto both sides. A through-hole 50a is formed onto a CCL50 (FIG. 4B) by such as dry etching method using the CCL50 (FIG. 4A) where each of the first conductive members (for instance copper foil) 52A and 52B is disposed onto each side of a flexible base 51 formed of polyimide, respectively.

(B22) A double-sided CCL 60 provided with a second conductive member 61 so as to cover an inner wall of the through-hole 50a and the first conductive members 52A and 52B provided on both sides is obtained by plating CCL50 where the through-hole 50a is disposed (FIG. 4C). The plated through-hole 50a is now called through-hole 60a.

(B23) A double-sided CCL 60′ provided with a circuit 61′ is obtained by forming a circuit 61′ by etching an area where the second conductive member 61 is superimposed onto the first conductive member 52A and 52B with the double-sided CCL 60 provided with the second conductive member 61 (FIG. 4D).

(B24) An alkaline treatment is conducted onto both surfaces at least where the circuit 61′ is disposed in the double-sided CCL 60′ (FIG. 4E). For instance, an alkaline treatment of both outer surfaces of the double-sided CCL60′ is conducted by spraying a concentration- and a temperature-regulated alkaline aqueous solution from a device in which the line speed is controlled to the base. Accordingly, an alkaline-treated double-sided CCL60″ is obtained.

(B25) A coverlay 71 is laminated onto a surface where the alkaline-treated circuit 61′ disposed on the double-sided CCL60″ in the previous step so as to contact the adhesive 72 is disposed. From the step above, a flexible printed circuit (hereinafter abbreviated as a FPC) 90 which consists of the coverlay 71 laminated onto the surface layer portion where the copper foil circuit is disposed (FIG. 4F). When this lamination is performed, pressure or heat may be applied toward the direction of the flexible base 51 from the coverlay 71 (from the external to internal direction) as required. In this case, as for types of the coverlay 71, a coverlay consisting of, for instance, the adhesive 72 and the flexible base 73 may be preferably used. Therefore, the FPC 90 provided with a coverlay on the surface layer portion of the double-side board as shown in FIG. 4F is formed from the steps B21 to B25.

Adhesion obtained from the alkaline treatment in the steps described above is further improved by restricting each condition of the alkaline treatment. In particular, preferred ranges of a concentration of the alkaline solution is 0.2 wt % or more and 4.0 wt % or less, an alkaline treatment time is 20 seconds or more and 200 seconds or less, and a temperature of the alkaline solution is 20° C. or more and 50° C. or less in both steps.

A solution used in an alkaline treatment in examples described later is sodium hydroxide aqueous solution; however, the brand and composition are not limited thereto. Furthermore, commercially available RO water is used in a rinsing treatment after the alkaline treatment in the present embodiment; however, calcium-treated water may be used if the effect of the alkaline treatment is not affected, hence the brand and composition are not limited thereto.

Note that a designated line may be provided to process a work-size flexible printed circuit board as a device to perform an alkaline treatment. However, a peeling step of a dry film resist used upon formation of a circuit is generally performed by an alkaline solution, hence the step may be combined. The same effect is achieved by any of these procedures. In particular, combining the steps described above is more preferable since it contributes to reducing the manufacturing cost of the flexible printed circuit boards.

### EXAMPLE

Hereinafter results of findings of each condition of alkaline treatment are described in terms of modifying a surface disposed on a conductive member (copper foil) by subjecting a single-sided CCL to an alkaline treatment and improving adhesion between a resist disposed thereon.

### Example 1

In this example, an aqueous sodium hydroxide solution [NaOH(aq)] was used as an alkaline solution for the alkaline treatment. The concentration of the alkaline solution was varied in a range of 0.1-10.0 [wt %], and a flexible printed circuit board (single-side board) as shown in FIG. 1D was manufactured according to the steps described above (A11) to (A13). Note that other manufacturing conditions except the concentration of the alkaline treatment were consistent. Table 1 summarizes the manufacturing conditions used in this Example 1, and the printed circuit board manufactured in this example is called sample S1.

TABLE 1
Composition of the printed circuit board:
Single-sided CCL; model number: PNS, copper foil thickness: 18 μm,
polyimide thickness: 25 μm, which is available from Arisawa
Manufacturing Co., Ltd.
Resist; model number: SS7100, resist thickness:
25 μm, which is available from Towa Gosei Co., Ltd.
Alkaline solution treatment condition of sample S1:
Alkaline treatment; concentration: 0.1-10.0 [wt %], treatment time:
30 seconds, solution temperature: 25° C.
RO water rinsing treatment; solution temperature: room temperature,
rinsing time: 30 seconds.

### Example 2

In this example, an aqueous sodium hydroxide solution [NaOH(aq)] was used as an alkaline solution for the alkaline treatment. The alkaline treatment time was varied in a range of 10 to 600 seconds, and a flexible printed circuit board (single-side board) as shown in FIG. 1D was manufactured according to the steps described above (A11) to (A13). Note that other manufacturing conditions except the alkaline treatment time were consistent with that of Example 1. Table 2 summarizes the manufacturing conditions used in this example 2, and the printed circuit board manufactured in this example is called sample S2.

TABLE 2
Composition of the printed circuit board:
Single-sided CCL; model number: PNS, copper foil thickness: 18 μm,
polyimide thickness: 25 μm, which is available from Arisawa
Manufacturing Co., Ltd.
Resist; model number: SS7100, resist thickness: 25 μm, which is
available from Towa Gosei Co., Ltd.
Alkaline solution treatment condition of sample S2:
Alkaline treatment; concentration: 1.0 [wt %], treatment time:
10-600 seconds, solution temperature: 25° C.
RO water rinsing treatment; solution temperature: room temperature,
rinsing time: 30 seconds.

### Example 3

In this example, an aqueous sodium hydroxide solution [NaOH(aq)] was used as an alkaline solution for the alkaline treatment. The alkaline solution temperature was varied in a range of 5 to 55° C., and a flexible printed circuit board (single-side board) as shown in FIG. 1D was manufactured according to the steps described above (A11) to (A13). Note that other manufacturing conditions except the alkaline treatment temperature were consistent with that of Example 1. Table 3 summarizes the manufacturing conditions used in this Example 3, and the printed circuit board manufactured in this example is called sample S3.

TABLE 3
Composition of the printed circuit board:
Single-sided CCL; model number: PNS, copper foil thickness: 18 μm,
polyimide thickness: 25 μm, which is available from Arisawa
Manufacturing Co., Ltd.
Resist; model number: SS7100, resist thickness: 25 μm, which is
available from Towa Gosei Co., Ltd.
Alkaline solution treatment condition of sample S3:
Alkaline treatment; concentration: 1.0 [wt %], treatment time:
30 seconds, solution temperature: 5 to 55° C.
RO water rinsing treatment; solution temperature: room temperature,
rinsing time: 30 seconds.

### Example 4

In this example, an aqueous sodium hydroxide solution [NaOH(aq)] was used as an alkaline solution for the alkaline treatment. The concentration of the alkaline treatment was varied in a range of 0.1 to 10.0 [wt %], and a flexible printed circuit board (single-side board) as shown in FIG. 2D was manufactured by following the steps described above (B11) to (B13). Note that other manufacturing conditions except the concentration of the alkaline solution were consistent. Table 4 summarizes the manufacturing conditions used in this Example 4, and the printed circuit board manufactured in this example is called sample S4.

TABLE 4
Composition of the printed circuit board:
Single-sided CCL; model number: PNS, copper foil thickness: 18 μm,
polyimide thickness: 25 μm, which is available from Arisawa
Manufacturing Co., Ltd.
CL film; model number: CISD, polyimide thickness: 25 μm, adhesive
thickness: 25 μm, which is available from Nikkan Industries Co., Ltd.
Alkaline solution treatment condition of sample S4:
Alkaline treatment; concentration: 0.1-10.0 [wt %], treatment time:
30 seconds, solution temperature: 25° C.
RO water rinsing treatment; solution temperature: room temperature,
rinsing time: 30 seconds.

### Example 5

In this example, an aqueous sodium hydroxide solution [NaOH(aq)] was used as the alkaline solution for the alkaline treatment. The alkaline treatment time was varied in a range of 10 to 600 seconds, and a flexible printed circuit board (single-side board) as shown in FIG. 2D was manufactured according to the steps described above (B11) to (B13). Note that other manufacturing conditions except the alkaline treatment time were consistent with that of Example 4. Table 5 summarizes the manufacturing conditions used in this Example 5, and the printed circuit board manufactured in this example is called sample S5.

TABLE 5
Composition of the printed circuit board:
Single-sided CCL; model number: PNS, copper foil thickness: 18 μm,
polyimide thickness: 25 μm, which is available from Arisawa
Manufacturing Co., Ltd.
CL film; model number: CISD, polyimide thickness: 25 μm, adhesive
thickness: 25 μm, which is available from Nikkan Industries Co., Ltd.
Alkaline solution treatment condition of sample S5:
Alkaline treatment; concentration: 1.0 [wt %], treatment time: 10-600
seconds, solution temperature: 25° C.
RO water rinsing treatment; solution temperature: room temperature,
rinsing time: 30 seconds.

### Example 6

In this example, an aqueous sodium hydroxide solution [NaOH(aq)] was used as an alkaline solution for the alkaline treatment. The alkaline solution temperature was varied in a range of 5 to 55° C., and a flexible printed circuit board (single-side board) as shown in FIG. 2D was manufactured according to the steps described above (B1) to (B13). Note that other manufacturing conditions except the alkaline treatment time were consistent with that of Example 4. Table 6 summarizes the manufacturing conditions used in this Example 6, and the printed circuit board manufactured in this example is called sample S6.

TABLE 6
Composition of the printed circuit board:
Single-sided CCL; model number: PNS, copper foil thickness: 18 μm,
polyimide thickness: 25 μm, which is available from Arisawa
Manufacturing Co., Ltd.
CL film; model number: CISD, polyimide thickness: 25 μm, adhesive
thickness: 25 μm, which is available from Nikkan Industries Co., Ltd.
Alkaline solution treatment condition of sample S6:
Alkaline treatment; concentration: 1.0 [wt %], treatment time:
30 seconds, solution temperature: 5 to 55° C.
RO water rinsing treatment; solution temperature: room temperature,
rinsing time: 30 seconds.

### Example 7

In this example, an aqueous sodium hydroxide solution [NaOH(aq)] was used as the alkaline solution for the alkaline treatment. The concentration of the alkaline solution was varied in a range of 0.1-10.0 [wt %], and a flexible printed circuit board (double-side board) as shown in FIG. 3D was manufactured according to the steps described above (A21)-(A25). Note that other manufacturing conditions except the concentration of the alkaline solution were consistent. Table 7 summarizes the manufacturing conditions used in this Example 7, and the printed circuit board manufactured in this example is called sample S7.

TABLE 7
Composition of the printed circuit board:
Double-sided CCL; model number: PKW, copper foil thickness: 18 μm,
polyimide thickness: 25 μm, which is available from Arisawa
Manufacturing Co., Ltd.
Resist; model number: SS7100, resist thickness: 25 μm, which is
available from Towa Gosei Co., Ltd.
Alkaline solution treatment condition of sample S7:
Alkaline treatment; concentration: 0.1-10.0 [wt %], treatment time:
30 seconds, solution temperature: 25° C.
RO water rinsing treatment; solution temperature: room temperature,
rinsing time: 30 seconds.

### Example 8

In this example, an aqueous sodium hydroxide solution [NaOH(aq)] was used as an alkaline solution for the alkaline treatment. The alkaline treatment time was varied in a range of 10-600 seconds, and a flexible printed circuit board (double-side board) as shown in FIG. 3F was manufactured according to the steps described above (A21) to (A25). Note that other manufacturing conditions except the alkaline treatment time were consistent with that of the Example 7. Table 8 summarizes the manufacturing conditions used in this Example 8, and the printed circuit board manufactured in this example is called sample S8.

TABLE 8
Composition of the printed circuit board:
Double-sided CCL; model number: PKW, copper foil thickness: 18 μm,
polyimide thickness: 25 μm, which is available from Arisawa
Manufacturing Co., Ltd.
Resist; model number: SS7100, resist thickness: 25 μm, which is
available from Towa Gosei Co., Ltd.
Alkaline solution treatment condition of sample S8:
Alkaline treatment; concentration: 1.0 [wt %], treatment time: 10-600
seconds, solution temperature: 25° C.
RO water rinsing treatment; solution temperature: at the room temperature,
rinsing time: 30 seconds.

### Example 9

In this example, an aqueous sodium hydroxide solution [NaOH(aq)] was used as an alkaline solution for the alkaline treatment. The alkaline solution temperature was varied in a range of 5 to 55° C., and a flexible printed circuit board (double-side board) as shown in FIG. 3F was manufactured according to the steps described above (A21) to (A25). Note that other manufacturing conditions except the alkaline treatment time were consistent with that of the Example 7. Table 9 summarizes the manufacturing conditions used in this Example 9, and the printed circuit board manufactured in this example is called sample S9.

TABLE 9
Composition of the printed circuit board:
Double-sided CCL; model number: PKW, copper foil thickness: 18 μm,
polyimide thickness: 25 μm, which is available from Arisawa
Manufacturing Co., Ltd.
Resist; model number: SS7100, resist thickness: 25 μm, which is
available from Towa Gosei Co., Ltd.
Alkaline solution treatment condition of sample S9:
Alkaline treatment; concentration: 1.0 [wt %], treatment time: 30
seconds, solution temperature: 5 to 55° C.
RO water rinsing treatment; solution temperature: room temperature,
rinsing time: 30 seconds.

### Example 10

In this example, an aqueous sodium hydroxide solution [NaOH(aq)] was used as an alkaline solution for the alkaline treatment. The concentration of the alkaline solution was varied in a range of 0.1-10.0 [wt %], and a flexible printed circuit board (double-side board) as shown in FIG. 4F was manufactured according to the steps described above (B21) to (B25). Note that other manufacturing conditions except the concentration of the alkaline solution were consistent. Table 10 summarizes the manufacturing conditions used in this Example 10, and the printed circuit board manufactured in this example is called sample S10.

TABLE 10
Composition of the printed circuit board:
Double-sided CCL; model number: PKW, copper foil thickness: 18 μm,
polyimide thickness: 25 μm, which is available from Arisawa
Manufacturing Co., Ltd.
CL film; model number: CISD, polyimide thickness: 25 μm, adhesive
thickness: 25 μm, which is available from Nikkan Industries Co., Ltd.
Alkaline solution treatment condition of sample S10:
Alkaline treatment; concentration: 0.1-10.0 [wt %], treatment time:
30 seconds, solution temperature: 25° C.
RO water rinsing treatment; solution temperature: room temperature,
rinsing time: 30 seconds.

### Example 11

In this example, an aqueous sodium hydroxide solution [NaOH(aq)] was used as the alkaline solution for the alkaline treatment. The alkaline treatment time was varied in a range of 10-600 seconds, and a flexible printed circuit board (double-side board) as shown in FIG. 4F was manufactured according to the steps described above (B21) to (B25). Note that other manufacturing conditions except the alkaline treatment time were consistent with that of the Example 10. Table 11 summarizes the manufacturing condition used in this Example 10, and the printed circuit board manufactured in this example is called sample S11.

TABLE 11
Composition of the printed circuit board:
Double-sided CCL; model number: PKW, copper foil thickness: 18 μm,
polyimide thickness: 25 μm, which is available from Arisawa
Manufacturing Co., Ltd.
CL film; model number: CISD, polyimide thickness: 25 μm, adhesive
thickness: 25 μm, which is available from Nikkan Industries Co., Ltd.
Alkaline solution treatment condition of sample S11:
Alkaline treatment; concentration: 1.0 [wt %], treatment time: 10-600
seconds, solution temperature: 25° C.
RO water rinsing treatment; solution temperature: room temperature,
rinsing time: 30 seconds.

### Example 12

In this example, an aqueous sodium hydroxide solution [NaOH(aq)] was used as an alkaline solution for the alkaline treatment. The alkaline solution temperature was varied in a range of 5 to 55° C., and a flexible printed circuit board (double-side board) as shown in FIG. 4F was manufactured according to the steps described above (B21)-(B25). Note that other manufacturing conditions except the alkaline solution temperature were consistent with that of the Example 10. Table 12 summarizes the manufacturing condition used in this Example 12, and the printed circuit board manufactured in this example is called sample S12.

TABLE 12
Composition of the printed circuit board:
Double-sided CCL; model number: PKW, copper foil thickness: 18 μm,
polyimide thickness: 25 μm, which is available from Arisawa
Manufacturing Co., Ltd.
CL film; model number: CISD, polyimide thickness: 25 μm, adhesive
thickness: 25 μm, which is available from Nikkan Industries Co., Ltd.
Alkaline solution treatment condition of sample S12:
Alkaline treatment; concentration: 1.0 [wt %], treatment time: 30 seconds,
solution temperature: 5 to 55° C.
RO water rinsing treatment; solution temperature: room temperature,
rinsing time: 30 seconds.

### Example 13

This example is the same as Example 7 except that six-layers of FPC substrate laminated with three of the double-side substrates were used instead. An aqueous sodium hydroxide solution [NaOH(aq)] was used as an alkaline solution for the alkaline treatment. The concentration of the alkaline treatment was varied in a range of 0.1-10.0 [wt %]. Note that other manufacturing conditions except the concentration of the alkaline solution were consistent. Table 13 summarizes the manufacturing conditions used in this Example 13, and the printed circuit board manufactured in this example is called sample S13.

TABLE 13
Composition of the printed circuit board:
Double-sided CCL; model number: PKW, copper foil thickness: 18 μm,
polyimide thickness: 25 μm, which is available from Arisawa
Manufacturing Co., Ltd.
Interlayer adhesive; model number: SAFD, adhesive thickness: 25 μm,
which is available from Nikkan Industries Co., Ltd.
Resist; model number: SS7100, resist thickness: 25 μm, which is available
from Towa Gosei Co., Ltd.
Alkaline solution treatment condition of sample S13:
Alkaline treatment; concentration: 0.1-10.0 [wt %], treatment time: 30
seconds, solution temperature: 25° C.
RO water rinsing treatment; solution temperature: room temperature,
rinsing time: 30 seconds.

### Example 14

In this example, by using an aqueous sodium hydroxide solution [NaOH(aq)] as the alkaline solution for the alkaline treatment, a flexible printed circuit board (six-layer board) was manufactured under the same conditions used in Example 13 except for changing the alkaline treatment time in a range of 10-600 seconds. Note that other manufacturing conditions except the alkaline treatment time were consistent. Table 14 summarizes the manufacturing conditions used in this Example 14, and the printed circuit board manufactured in this example is called sample S14.

TABLE 14
Composition of the printed circuit board:
Double-sided CCL; model number: PKW, copper foil thickness: 18 μm,
polyimide thickness: 25 μm, which is available from Arisawa
Manufacturing Co., Ltd.
Interlayer adhesive; model number: SAFD, adhesive thickness: 25 μm,
which is available from Nikkan Industries Co., Ltd.
Resist; model number: SS7100, resist thickness: 25 μm, which is available
from Towa Gosei Co., Ltd.
Alkaline solution treatment condition of sample S14:
Alkaline treatment; concentration: 1.0 [wt %], treatment time:
10-600 seconds, solution temperature: 25° C.
RO water rinsing treatment; solution temperature: room temperature,
rinsing time: 30 seconds.

### Example 15

In this example, by using an aqueous sodium hydroxide solution [NaOH(aq)] as an alkaline solution for the alkaline treatment, a flexible printed circuit board (six-layer board) was manufactured under the same conditions used in Example 13 except for changing the alkaline solution temperature in a range of 5-55° C. Note that other manufacturing conditions except the alkaline solution temperature were consistent. Table 15 summarizes the manufacturing conditions used in this Example 15, and the printed circuit board manufactured in this example is called sample S15.

TABLE 15

Composition of the printed circuit board:
Double-sided CCL; model number: PKW, copper foil thickness: 18 μm,
polyimide thickness: 25 μm, which is available from Arisawa
Manufacturing Co., Ltd.
Interlayer adhesive; model number: SAFD, adhesive thickness: 25 μm,
which is available from Nikkan Industries Co., Ltd.
Resist; model number: SS7100, resist thickness: 25 μm, which is available
from Towa Gosei Co., Ltd.
Alkaline solution treatment condition of sample S15:
Alkaline treatment; concentration: 1.0 [wt %], treatment time: 30
seconds, solution temperature: 5-55° C.
RO water rinsing treatment; solution temperature: room temperature,
rinsing time: 30 seconds.

### Example 16

This example is the same as Example 10 except that six-layers of FPC substrate laminated with three of the double-side substrates were used instead. An aqueous sodium hydroxide solution [NaOH(aq)] was used as an alkaline solution for the alkaline treatment. The concentration of the alkaline treatment was varied in a range of 0.1-10.0 [wt %]. Note that other manufacturing conditions except the concentration of the alkaline solution were consistent. Table 16 summarizes the manufacturing conditions used in Example 16, and the printed circuit board manufactured in this example is called sample S16.

TABLE 16

Composition of the printed circuit board:
Double-sided CCL; model number: PKW, copper foil thickness: 18 μm,
polyimide thickness: 25 μm, which is available from Arisawa
Manufacturing Co., Ltd.
Interlayer adhesive; model number: SAFD, adhesive thickness: 25 μm,
which is available from Nikkan Industries Co., Ltd.
CL film; model number: CISD, polyimide thickness: 25 μm, adhesive
thickness: 25 μm, which is available from Nikkan Industries Co., Ltd.
Alkaline solution treatment condition of sample S16:
Alkaline treatment; concentration: 0.1-10.0 [wt %], treatment time: 30
seconds, solution temperature: 25° C.
RO water rinsing treatment; solution temperature: room temperature,
rinsing time: 30 seconds.

### Example 17

In this example, by using an aqueous sodium hydroxide solution [NaOH(aq)] as an alkaline solution for the alkaline treatment, a flexible printed circuit board (six-layer board) were manufactured under the same condition used in Example 16 except for changing the alkaline treatment time in a range of 10-600 seconds. Note that other manufacturing conditions except the alkaline treatment time were consistent. Table 17 summarizes the manufacturing conditions used in this Example 17, and the printed circuit board manufactured in this example is called sample S17.

TABLE 17
Composition of the printed circuit board:
Double-sided CCL; model number: PKW, copper foil thickness: 18 μm,
polyimide thickness: 25 μm, which is available from Arisawa
Manufacturing Co., Ltd.
Interlayer adhesive; model number: SAFD, adhesive thickness: 25 μm,
which is available from Nikkan Industries Co., Ltd.
CL film; model number: CISD, polyimide thickness: 25 μm, adhesive
thickness: 25 μm, which is available from Nikkan Industries Co., Ltd.
Alkaline solution treatment condition of sample S17:
Alkaline treatment; concentration: 1.0 [wt %], treatment time: 10-600
seconds, solution temperature: 25° C.
RO water rinsing treatment; solution temperature: at the room temperature,
rinsing time: 30 seconds.

### Example 18

In this example, by using an aqueous sodium hydroxide solution [NaOH(aq)] as an alkaline solution for the alkaline treatment, a flexible printed circuit board (six-layer board) were manufactured under the same condition used in Example 16 except for changing the alkaline solution temperature in a range of 5 to 55° C. Note that other manufacturing conditions except the alkaline solution temperature were consistent. Table 15 summarizes the manufacturing conditions used in this Example 18, and the printed circuit board manufactured in this example is called sample S18.

TABLE 18
Composition of the printed circuit board:
Double-sided CCL; model number: PKW, copper foil thickness: 18 μm,
polyimide thickness: 25 μm, which is available from Arisawa
Manufacturing Co., Ltd.
Interlayer adhesive; model number: SAFD, adhesive thickness: 25 μm,
which is available from Nikkan Industries Co., Ltd.
CL film; model number: CISD, polyimide thickness: 25 μm, adhesive
thickness: 25 μm, which is available from Nikkan Industries Co., Ltd.
Alkaline solution treatment condition of sample S18:
Alkaline treatment; concentration: 1.0 [wt %], treatment time: 30 seconds,
solution temperature: 5 to 55° C.
RO water rinsing treatment; solution temperature: room temperature,
rinsing time: 30 seconds.

(Peel Strength Test)

A peel strength test based on JIS C 6471 was carried out for samples S1 to S18 obtained from the examples above. Tensile speed was 50 mm/min and test temperature was normal temperature (room temperature). A peel strength (in the unit of N/cm) was calculated based on JIS C 5016 8.1.6. A mean value was obtained with the number (N) of samples 50 (N=50) for each condition.

(Concentration of Alkaline Solution Dependency)

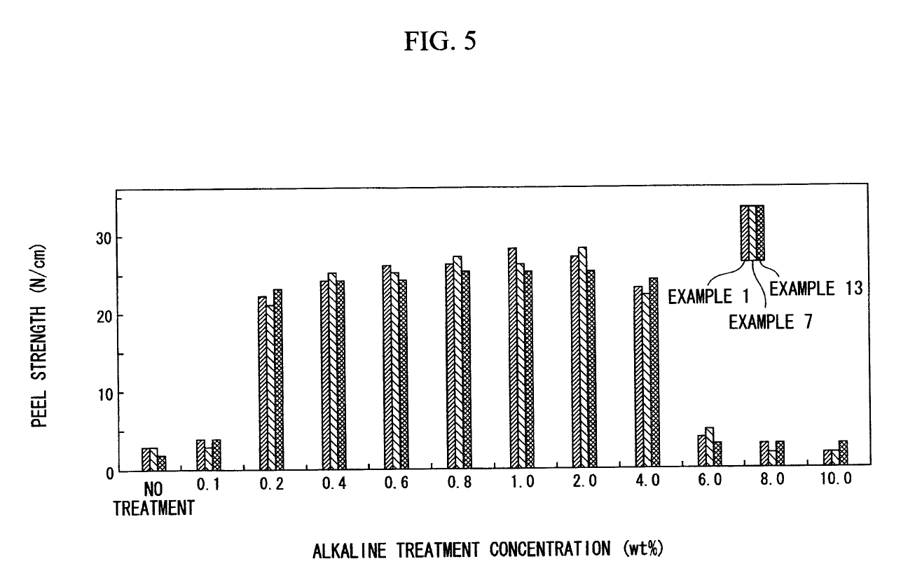

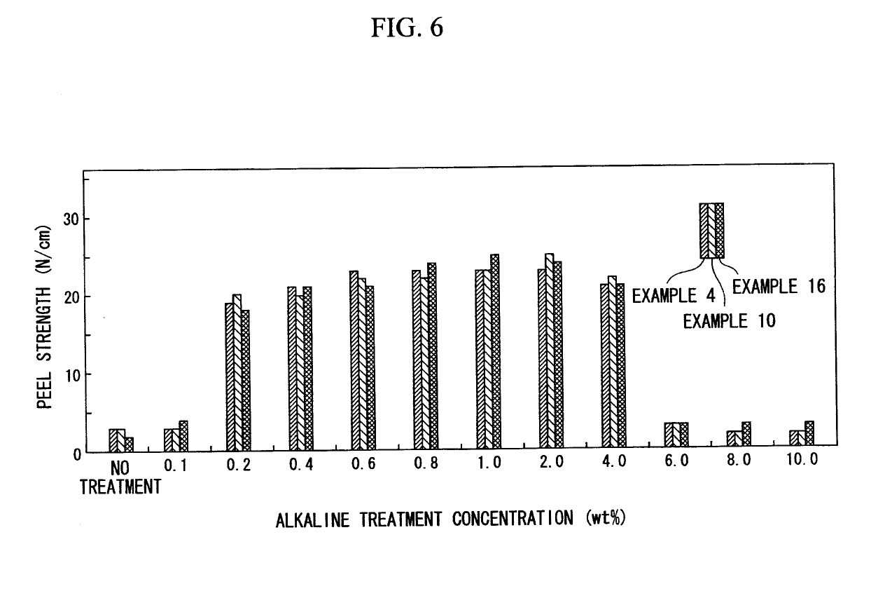

FIGS. 5 and 6 are graphs which summarize the results of peel strength obtained from samples manufactured using various concentrations of the alkaline solution (indicated as alkaline treatment concentration in each figure). FIGS. 5 and 6 show results from Examples 1, 7 and 13; and from Examples 4, 10 and 16, respectively.

The following points are apparent from FIG. 5.

(C1a) If the concentration of the alkaline solution is 0.1 wt % or less, the alkaline treatment is insufficient in that the peel strength is low.

(C1b) In contrast, if the concentration of the alkaline solution is 6.0 wt % or more, the alkaline treatment is excessive in that the peel strength is low.

(C1c) If the concentration of the alkaline solution is 0.2 wt % or more and 4.0 wt % or less, a peel strength of about five times higher than that with no treatment can be stably obtained.

(C1d) The above results are independent of the structure of the flexible print circuit; such as single-side board (Example 1), double-side board (Example 7) and multi-layer board (Example 13), and a high peel strength is obtained within the same concentration of the alkaline solution.

Accordingly, in the FPC, in order to modify a surface where a conductive member (copper foil) is provided and to improve adhesive strength between the resist disposed thereon and to maintain a stable peel strength, it can be seen that the concentration of the alkaline solution needs to fall within an appropriate range.

Furthermore, the same result as FIG. 5 is obtained in the graph of FIG. 6, which summarizes the results from three examples; Examples 4, 10 and 16 where the CL film was provided instead of the resist. Accordingly, in the FPC, in order to modify a surface where a conductive member (copper foil) is provided and to improve adhesive strength between the CL film disposed thereon and to maintain a stable peel strength, it can be seen that the concentration of the alkaline solution needs to fall within an appropriate range.

Alkaline Treatment Time Dependency:

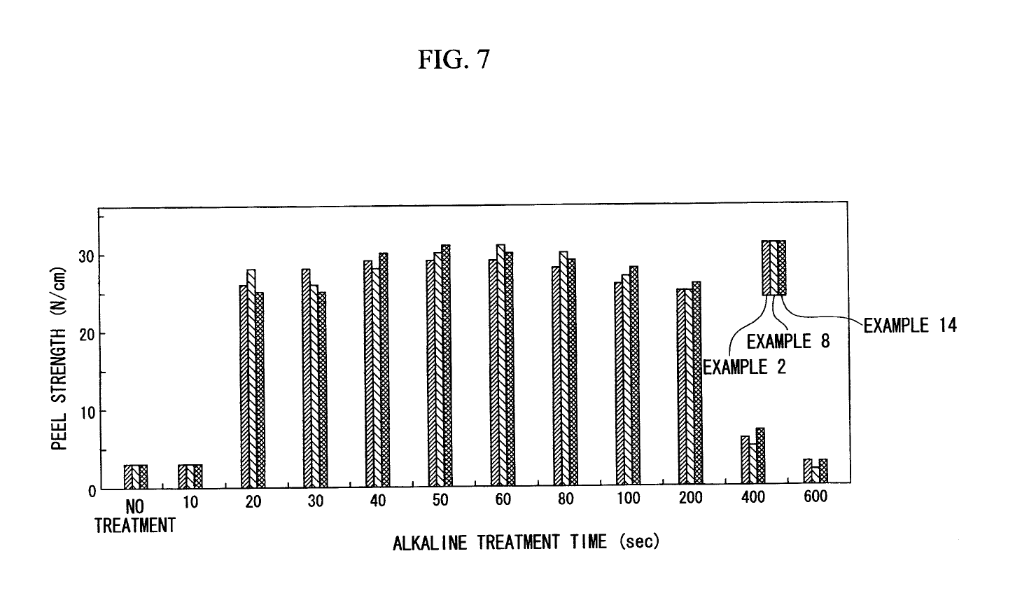

FIGS. 7 and 8 are graphs which summarize the results of peel strength obtained from samples manufactured using various alkaline treatment times (indicated as alkaline treatment time in each figure). FIGS.7 and 8 show results from Examples 2, 8 and 14; and from Examples 5, 11 and 17, respectively.

The following points are apparent from FIG. 7.

(C2a) If the alkaline treatment time is 10 seconds or less, the alkaline treatment is insufficient in that the peel strength is low.

(C2b) In contrast, if the alkaline treatment time is 400 seconds or more, the alkaline treatment is excessive in that the peel strength is low.

(C2c) If the alkaline treatment time is 20 seconds or more and 200 seconds or less, a peel strength of about six times higher than that of no treatment can be stably obtained.

(C2d) The above results are independent on the structure of the flexible print circuit such as single-side board (Example 2), double-side board (Example 8) and multi-layer board (Example 14), and a high peel strength is obtained within the same alkaline treatment time.

Accordingly, in the FPC, in order to modify a surface where a conductive member (copper foil) is provided and to improve adhesive strength between the resist disposed thereon and to maintain a stable peel strength, it can be seen that the alkaline treatment time needs to fall within an appropriate range.

Furthermore, the same result as FIG. 7 is obtained in FIG. 8, which summarizes the results from three examples; Examples 5, 11 and 17 where the CL film was provided instead of the resist. Accordingly, in the FPC, in order to modify a surface where a conductive member (copper foil) is provided and to improve adhesive strength between the CL film disposed thereon and to maintain a stable peel strength, it can be seen that the alkaline treatment time needs to fall within an appropriate range.

Alkaline Solution Temperature Dependency:

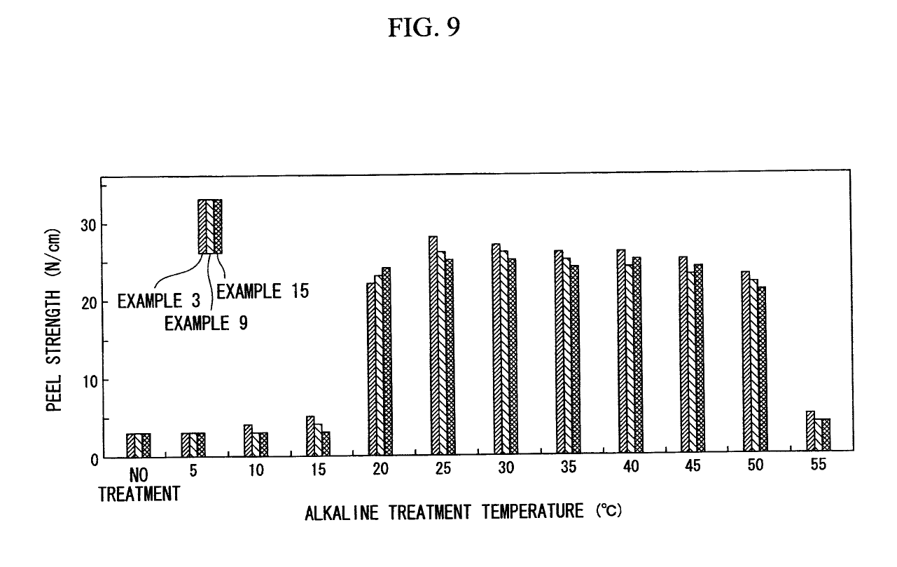

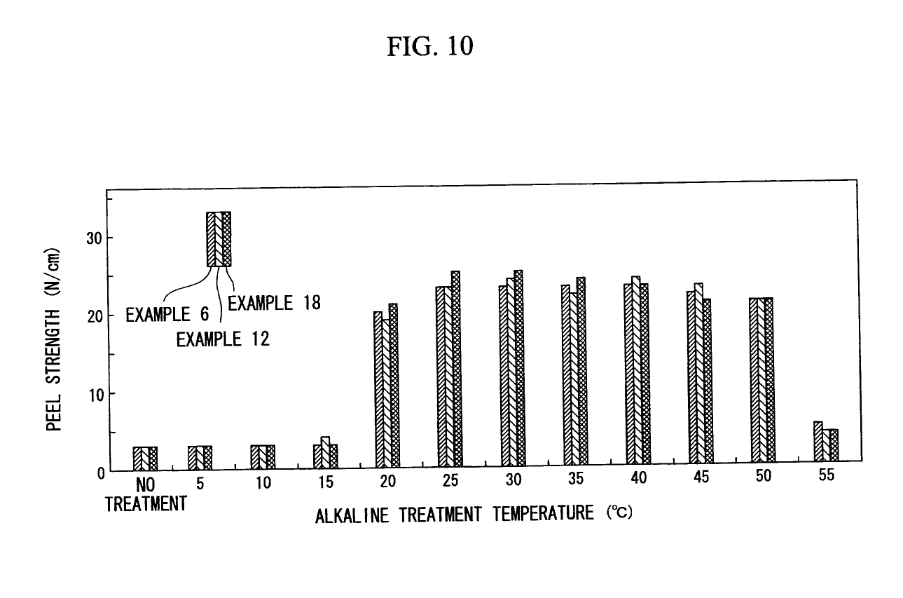

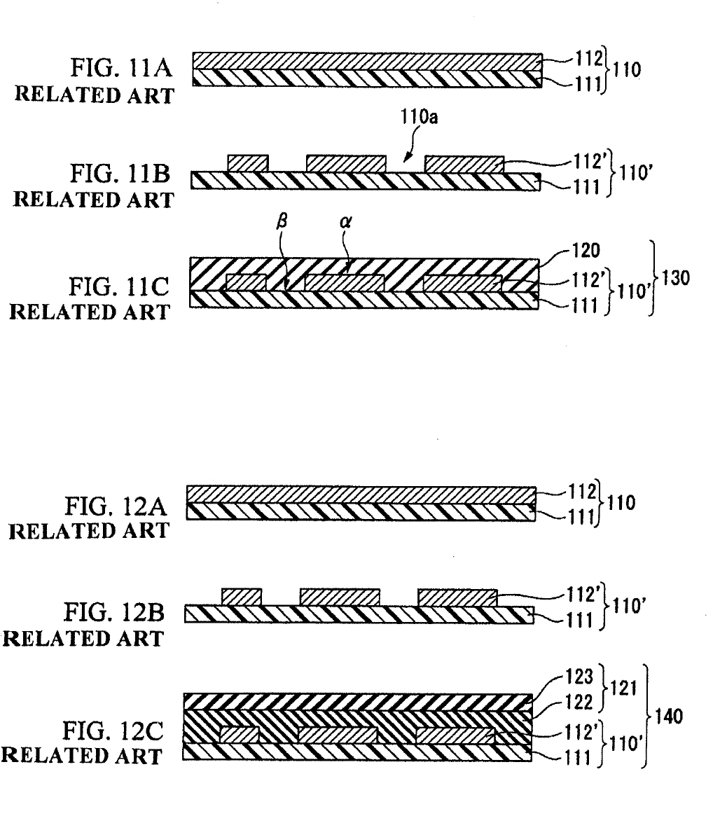

FIGS. 9 and 10 are graphs which summarize the results of peel strength obtained from samples manufactured by various alkaline solution temperatures (indicated as alkaline solution temperature in each figure). FIGS. 9 and 10 show results from Examples 3, 9 and 15; and from Examples 6, 12 and 18, respectively.

The following points are apparent from FIG. 9.

(C3a) If the alkaline solution temperature is 15° C. or less, the alkaline treatment is insufficient in that the peel strength is low.

(C3b) In contrast, if the alkaline solution temperature is 55° C. or more, the alkaline treatment is excessive in that the peel strength is low.

(C3c) If the alkaline solution temperature is 20° C. or more and 50° C. or less, the peel strength of about five times higher than that with no treatment can be stably obtained.

(C3d) The above results are independent on the structure of the flexible print circuit; such as single-side board (Example 3), double-side board (Example 9) and multi-layer board (Example 15), a high peel strength is obtained within the same alkaline solution temperature.

Accordingly, in the FPC, in order to modify a surface where a conductive member (copper foil) is provided and to improve adhesive strength between the resist disposed thereon and to maintain a stable peel strength, it can be seen that the alkaline solution temperature needs to fall within an appropriate range.

Furthermore, the same result as FIG. 9 is obtained in the graph of FIG. 10 which summarizes the results from three examples; Examples 6, 12 and 18 where the CL film was provided instead of the resist. Accordingly, in the FPC, in order to modify a surface where a conductive member (copper foil) is provided and to improve adhesive strength between the CL film disposed thereon and to maintain a stable peel strength, it can be seen that the alkaline solution temperature needs to fall within an appropriate range.

In general, it is known that a multi-layered FPC with a low peel strength is low in reliability in various reliability tests including a heat cycle test, a heat shock test (in a vapor phase or a liquid phase), a pressure cooker test (PCT), a HAST test, a reflow test, and so on. In other words, in a test in which deterioration of a multi-layered FPC is accelerated due to change in temperature, humidity and pressure, low peel strength is equivalent to low adhesion at particular sites; and consequently, those particular sites are likely to be peeled off, which results in insufficient and poor insulation of copper circuits.

On the contrary, high peel strength is equivalent to high adhesion at particular sites, and consequently, those particular sites are hardly peeled off in various reliability tests. Accordingly, an increase of peel strength contributes to an increase of reliability of multi-layered FPC.

According to exemplary embodiments of the present invention, when manufacturing a flexible printed circuit board consisting of a single-side board, double-side board or multi-layer board which are provided with a surface layer portion where a copper foil circuit is disposed, the FPC can prevent peeling from occurring between the surface layer portion and the resist or coverlay disposed thereon. The manufacturing method includes disposing the resist or coverlay onto the alkaline-treated surface layer portion after modifying the surface layer portion by subjecting it to alkaline treatment. Therefore, the exemplary embodiments contribute to providing a reliable flexible printed circuit board with stable adhesion.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of manufacturing a flexible printed circuit board having a surface layer portion where a copper foil circuit is disposed and consisting of single-side board, double-side board and multi-layer board, the method comprising at least the steps of:
subjecting the surface layer portion to alkaline treatment; and
disposing a resist onto the alkaline-treated surface layer portion, wherein;
a concentration of an alkaline solution is 0.2 wt % or more and 4.0 wt % or less, alkaline treatment time is 20 seconds or more and 200 seconds or less, and a temperature of the alkaline solution is 20° C. or more and 50° C. or less.

2. A method of manufacturing a flexible printed circuit board having a surface layer portion where a copper foil circuit is disposed and consisting of single-side board, double-side board and multi-layer board, the method comprising at least the steps of:
subjecting the surface layer portion to alkaline treatment; and
disposing a coverlay onto the alkaline-treated surface layer portion so as to attach an adhesive,
wherein;
a concentration of an alkaline solution is 0.2 wt % or more and 4.0 wt % or less, alkaline treatment time is 20 seconds or more and 200 seconds or less, and a temperature of the alkaline solution is 20° C. or more and 50° C. or less.
